(19) United States
(12) Patent Application Publication
(10) Pub. No.: US 2022/0367470 A1
(43) Pub. Date: Nov. 17, 2022

(54) METHOD FOR MANUFACTURING MEMORY DEVICE USING SEMICONDUCTOR ELEMENT

(71) Applicant: Unisantis Electronics Singapore Pte. Ltd., Singapore (SG)

(72) Inventors: Nozomu HARADA, Tokyo (JP); Koji SAKUI, Tokyo (JP)

(21) Appl. No.: 17/741,956

(22) Filed: May 11, 2022

(30) Foreign Application Priority Data
May 13, 2021 (JP) PCT/JP2021/018249

(51) Int. Cl. H01L 27/108; G11C 11/404; G11C 11/4096

(52) U.S. Cl. CPC H01L 27/10802; G11C 11/404; G11C 11/4096

(57) ABSTRACT

There are provided the steps of forming an N⁺ layer 21a and a Si pillar 26 on a substrate 20, the N⁺ layer 21a being connected to a source line SL, the Si pillar 26 standing in a vertical direction and being composed of a P⁺ layer 22a in a center portion thereof and a P layer 25a surrounding the P⁺ layer 22a; forming an N⁺ layer 3b and HfO₂ layers 28a and 28b of gate insulating layers on the P⁺ layer 22a, the N⁺ layer 3b being connected to a bit line BL, the HfO₂ layers 28a and 28b surrounding the Si pillar 26; and forming a TiN layer 30a of a gate conductor layer and a TiN layer 30b of a gate conductor layer, the TiN layer 30a surrounding the HfO₂ layer 28a and being connected to a plate line PL, the TiN layer 30b surrounding the HfO₂ layer 28b and being connected to a word line WL. Voltages to be applied to the source line SL, the plate line PL, the word line WL, and the bit line BL are controlled to perform a data write operation for holding a hole group generated by an impact ionization phenomenon or a gate induced drain leakage current in the Si pillar 26 and a data erase operation for discharging the hole group from within the Si pillar 26.

### CROSS-REFERENCE TO RELATED APPLICATIONS

This application claims priority to PCT/JP2021/018249 filed May 13, 2021, the enter content of which is incorporated herein by reference.

### TECHNICAL FIELD

The present invention relates to a method for manufacturing a memory device using a semiconductor element.

### BACKGROUND ART

Recent development of LSI (Large Scale Integration) technology requires high integration and high performance of memory elements.

In typical planar MOS transistors, a channel extends in a horizontal direction along an upper surface of a semiconductor substrate. In contrast, a channel of SGTs extends in a direction vertical to the upper surface of the semiconductor substrate (see, for example, PTL 1 and NPL 1). This enables the SGTs to achieve a high-density semiconductor device compared with the planar MOS transistors. Such SGTs can be used as selection transistors to implement high-integration memories such as a DRAM (Dynamic Random Access Memory, see, for example, NPL 2) to which a capacitor is connected, a PCM (Phase Change Memory, see, for example, NPL 3) to which a resistance change element is connected, an RRAM (Resistive Random Access Memory, see, for example, NPL 4), and an MRAM (Magneto-resistive Random Access Memory, see, for example, NPL 5) in which a change in magnetic spin orientation is induced by current to change resistance. Further, a capacitorless DRAM memory cell (see NPL 6) constituted by a single MOS transistor, and the like are available. The present application relates to a dynamic flash memory that does not include a resistance change element or a capacitor and that can be constituted only by MOS transistors.

FIGS. 10A to 10D illustrate a write operation of the capacitorless DRAM memory cell described above, which is constituted by a single MOS transistor, FIGS. 11A and 11B illustrate a problem in operation, and FIGS. 12A to 12C illustrate a read operation (see NPL 7).

FIGS. 10A to 10D illustrate the write operation of the DRAM memory cell. FIG. 10A illustrates a “1” write state. Here, the memory cell is formed on an SOI substrate 100 and is constituted by a source N⁺ layer 103 (semiconductor regions containing donor impurities at high concentrations are hereinafter referred to as “N⁺ layers”) to which a source line SL is connected, a drain N⁺ layer 104 to which a bit line BL is connected, a gate conductive layer 105 to which a word line WL is connected, and a floating body 102 of a MOS transistor 110a; the capacitorless DRAM memory cell is constituted by the single MOS transistor 110a. A SiO₂ layer 101 of the SOI substrate 100 is immediately below and in contact with the floating body 102. To write “1” to the memory cell constituted by the single MOS transistor 110a, the MOS transistor 110a is operated in a saturation region. That is, an electron channel 107 extending from the source N⁺ layer 103 has a pinch-off point 108 and does not reach the drain N⁺ layer 104 to which the bit line BL is connected. When the MOS transistor 110a is operated such that the bit line BL connected to the drain N⁺ layer 104 and the word line WL connected to the gate conductive layer 105 are both set to be at a high voltage and the gate voltage is set to about ½ of the drain voltage, the electric field strength is maximized at the pinch-off point 108 near the drain N⁺ layer 104. As a result, accelerated electrons flowing from the source N⁺ layer 103 toward the drain N⁺ layer 104 collide with a Si lattice, and the kinetic energy lost at this time causes generation of electron-hole pairs. Most of the generated electrons (not illustrated) reach the drain N⁺ layer 104. A very small number of electrons, which are very hot, jump over a gate oxide film 109 and reach the gate conductive layer 105. Holes 106, which are generated at the same time, charge the floating body 102. In this case, the generated holes 106 contribute as an increment of the majority carriers because the floating body 102 is made of P-type Si. When the floating body 102 is filled with the generated holes 106 and the voltage of the floating body 102 becomes higher than that of the source N⁺ layer 103 by Vb or more, the generated holes 106 are further discharged to the source N⁺ layer 103. Here, Vb is the built-in voltage across a PN junction between the source N⁺ layer 103 and the P-layer floating body 102 and is about 0.7 V. FIG. 10B illustrates a state in which the floating body 102 is charged to saturation with the generated holes 106.

Next, a “0” write operation of a memory cell 110 will be described with reference to FIG. 10C. A selected word line WL is common to the memory cell 110a for writing “1” and a memory cell 110b for writing “0”, which are present randomly. FIG. 10C illustrates a state of rewriting from the “1” write state to a “0” write state. To write “0”, the voltage of the bit line BL is set to a negative bias, and the PN junction between the drain N⁺ layer 104 and the P-layer floating body 102 is forward biased. As a result, the holes 106 in the floating body 102, which are generated in advance in the previous cycle, flow into the drain N⁺ layer 104 connected to the bit line BL. At the completion of the write operation, the following two memory cell states are obtained: the memory cell 110a filled with the generated holes 106 (FIG. 10B) and the memory cell 110b from which the generated holes 106 are injected (FIG. 10C). The floating body 102 of the memory cell 110a filled with the holes 106 has a higher potential than the floating body 102 having no generated holes. Thus, a threshold voltage of the memory cell 110a is lower than a threshold voltage of the memory cell 110b. This state is illustrated in FIG. 10D.

Next, a problem in the operation of the memory cell constituted by the single MOS transistor will be described with reference to FIGS. 11A and 11B. As illustrated in FIG. 11A, the floating body 102 has a capacitance C_{FB}, which is the sum of a capacitance C_{WL} between the gate to which the word line WL is connected and the floating body 102, a junction capacitance C_{SL} of the PN junction between the source N⁺ layer 103 to which the source line SL is connected and the floating body 102, and a junction capacitance C_{BL} of the PN junction between the drain N⁺ layer 104 to which the bit line BL is connected and the floating body 102. The capacitance C_{FB} is expressed by the following equation.

C_{FB}=C_{WL}+C_{BL}+C_{SL} (2)

Accordingly, an oscillation of a word line voltage V_{WL} at the time of writing affects the voltage of the floating body 102 serving as a storage node (junction) of the memory cell. This state is illustrated in FIG. 11B. In response to an increase in the word line voltage V_{WL} from 0 V to V_{ProgWL} at the time of writing, a voltage V_{FB} of the floating body 102 increases from a voltage V_{FB1} in the initial state before the change in the word line voltage V_{WL} to V_{FB2} due to capacitive coupling with the word line WL. The amount of voltage change ΔV_{FB} is expressed by the following equation.

ΔV_{FB}=V_{FB2}−V_{FB1}=C_{WL}/(C_{WL}+C_{BL}+C_{SL})×V_{ProgWL} (3)

### Here,

β=C_{WL}/(C_{WL}+C_{BL}+C_{SL}) (4)

β represents a coupling ratio. In such a memory cell, the contribution ratio of C_{WL} is high, and, for example, C_{WL}:C_{BL}:C_{SL}=8:1:1. In this case, β is equal to 0.8. For example, when the word line WL changes from 5 V at the time of writing to 0 V after the completion of writing, the floating body 102 is subjected to an amplitude noise of 5V×β=4 V due to the capacitive coupling between the word line WL and the floating body 102. This causes a problem that a sufficient potential difference margin is not provided between the “1” potential and the “0” potential of the floating body at the time of writing.

FIGS. 12A to 12C illustrate the read operation. FIG. 12A illustrates a “1” write state, and FIG. 12B illustrates a “0” write state. Actually, however, even if Vb is written in the floating body 102 by “1” writing, the floating body 102 is lowered to a negative bias when the word line WL returns to 0 V in response to the completion of writing. When “0” is written, the floating body 102 is lowered to a further negative bias, which makes it difficult to provide a sufficiently large potential difference margin between “1” and “0” at the time of writing, as illustrated in FIG. 12C. The small operation margin is a major problem of the DRAM memory cell. In addition, another issue is to increase the density of such DRAM memory cells.

### CITATION LIST

### Patent Literature

[PTL 1] Japanese Unexamined Patent Application Publication No. 2-188966

### Non Patent Literature

[NPL 1] Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)
[NPL 2] H. Chung, H. Kim, H. Kim, K. Kim, S. Kim, K. Dong, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)
[NPL 3] H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No 12, December, pp. 2201-2227 (2010)
[NPL 4] T. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V,” IEDM (2007)
[NPL 5] W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015)
[NPL 6] M. G. Ertosum, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010)
[NPL 7] E. Yoshida, and T. Tanaka: “A Capacitorless 1T-DRAM Technology Using Gate-Induced Drain-Leakage (GIDL) Current for Low-Power and High-Speed Embedded Memory,” IEEE Transactions on Electron Devices, Vol. 53, No. 4, pp. 692-697, April 2006.

### SUMMARY OF INVENTION

### Technical Problem

A capacitorless single-transistor DRAM (gain cell) in a memory device using an SGT has a problem that oscillation of the potential of the word line at the time of reading or writing data is directly transmitted as noise to an SGT body in a floating state because the capacitive coupling between the word line and the SGT body is large. This causes a problem of erroneous reading or erroneous rewriting of stored data, and makes it difficult to put a capacitorless single-transistor DRAM (gain cell) into practical use. In addition to overcoming the problem described above, it is necessary to achieve high performance and high density of DRAM memory cells.

### Solution to Problem

To overcome the problem described above, a method for manufacturing a memory device according to the present invention is

a method for manufacturing a memory device using a semiconductor element, the memory device being configured to control voltages to be applied to a first gate conductor layer, a second gate conductor layer, a first impurity layer, and a second impurity layer to perform a data write operation, a data read operation, and a data erase operation, the method including the steps of:

forming a semiconductor pillar standing on a substrate in a vertical direction to the substrate and having a third impurity layer and a fourth impurity layer on either or both of a lower portion and an upper portion of the semiconductor pillar, the third impurity layer being located in a central portion of the semiconductor pillar as viewed in a horizontal cross section, the fourth impurity layer surrounding the third impurity layer and having a lower impurity concentration than the third impurity layer;

forming a first gate insulating layer surrounding a side surface of a first semiconductor pillar in the lower portion of the semiconductor pillar;

forming the first gate conductor layer surrounding a side surface of the first gate insulating layer;

forming a second gate insulating layer connected to the first gate insulating layer and surrounding a side surface of a second semiconductor pillar in the upper portion of the semiconductor pillar;

forming the second gate conductor layer so as to surround a side surface of the second gate insulating layer;

forming the first impurity layer connected to a bottom portion of the semiconductor pillar before or after forming the semiconductor pillar; and

forming the second impurity layer at a top portion of the semiconductor pillar before or after forming the semiconductor pillar (first aspect of the invention).

In the first invention, the third impurity layer is formed to be connected to the first impurity layer and the second impurity layer, and the fourth impurity layer is formed to be connected to the first impurity layer and the second impurity layer (second aspect of the invention).

In the first aspect of the invention, the method further includes the steps of:

forming a first impurity layer pillar having the third impurity layer at least in a lower portion thereof; and

forming the fourth impurity layer so as to surround the first impurity layer pillar to form the semiconductor pillar (third aspect of the invention).

In the first aspect of the invention, the second semiconductor pillar surrounded by the second gate insulating layer is formed of a fifth impurity layer having a lower impurity concentration than the first impurity layer (fourth aspect of the invention).

In the fourth aspect of the invention, the semiconductor pillar is formed such that, in plan view, an outer peripheral edge of a portion of the semiconductor pillar surrounded by the second gate insulating layer is inside an outer peripheral edge of a portion of the semiconductor pillar surrounded by the first gate insulating layer (fifth aspect of the invention).

In the above fourth aspect of the invention, the third impurity layer and the fourth impurity layer are formed as different semiconductor material layers (sixth aspect of the invention).

In the first aspect of the invention, a first gate capacitance between the first gate conductor layer and the semiconductor pillar is larger than a second gate capacitance between the second gate conductor layer and the semiconductor pillar (seventh aspect of the invention).

In the first aspect of the present invention, the memory device is configured to perform the data write operation for controlling the voltages to be applied to the first gate conductor layer, the second gate conductor layer, the first impurity layer, and the second impurity layer to hold in the semiconductor pillar a hole group or an electron group serving as majority carriers in the semiconductor pillar, the hole group or electron group being formed by an impact ionization phenomenon or a gate induced drain leakage current, and perform the data erase operation for controlling the voltages to be applied to the first gate conductor layer, the second gate conductor layer, the first impurity layer, and the second impurity layer to discharge the hole group or the electron group serving as the majority carriers in the semiconductor pillar from within the semiconductor pillar (eighth aspect of the present invention).

### BRIEF DESCRIPTION OF DRAWINGS

FIG. 1 is a structural diagram of a memory device including an SGT according to a first embodiment.

FIGS. 2A, 2B, and 2C are diagrams for describing an erase operation mechanism of the memory device including an SGT according to the first embodiment.

FIGS. 3A, 3B, and 3C are diagrams for describing a write operation mechanism of the memory device including an SGT according to the first embodiment.

FIGS. 4AA, 4AB, and 4AC are diagrams for describing a read operation mechanism of the memory device including an SGT according to the first embodiment.

FIGS. 4BA, 4BB, 4BC, and 4BD are diagrams for describing the read operation mechanism of the memory device including an SGT according to the first embodiment.

FIGS. 5AA and 5AB are structural diagrams illustrating a method for manufacturing the memory device including an SGT according to the first embodiment.

FIGS. 5BA and 5BB are structural diagrams illustrating the method for manufacturing the memory device including an SGT according to the first embodiment.

FIGS. 5CA and 5CB are structural diagrams illustrating the method for manufacturing the memory device including an SGT according to the first embodiment.

FIGS. 5DA and 5DB are structural diagrams illustrating the method for manufacturing the memory device including an SGT according to the first embodiment.

FIGS. 5EA and 5EB are structural diagrams illustrating the method for manufacturing the memory device including an SGT according to the first embodiment.

FIGS. 5FA and 5FB are structural diagrams illustrating the method for manufacturing the memory device including an SGT according to the first embodiment.

FIGS. 5GA and 5GB are structural diagrams illustrating the method for manufacturing the memory device including an SGT according to the first embodiment.

FIG. 6 is a structural diagram of a memory device including an SGT according to a second embodiment.

FIGS. 7AA and 7AB are structural diagrams illustrating a method for manufacturing the memory device including an SGT according to the second embodiment.

FIGS. 7BA and 7BB are structural diagrams illustrating the method for manufacturing the memory device including an SGT according to the second embodiment.

FIG. 8 is a structural diagram of a memory device including an SGT according to a third embodiment.

FIGS. 9AA and 9AB includes structural diagrams illustrating a method for manufacturing the memory device including an SGT according to the third embodiment.

FIGS. 9BA and 9BB are structural diagrams illustrating the method for manufacturing the memory device including an SGT according to the third embodiment.

FIGS. 10A, 10B, 10C, and 10D are diagrams illustrating a write operation of a capacitorless DRAM memory cell of the related art.

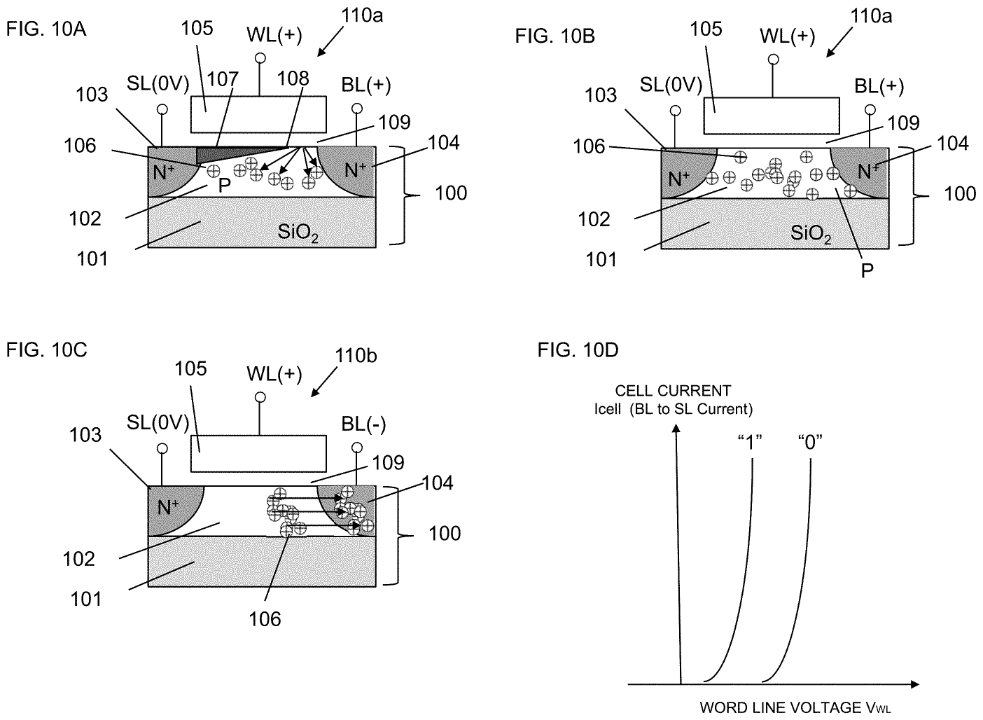

FIGS. 11A and 11B are diagrams for describing a problem in the operation of the capacitorless DRAM memory cell of the related art.

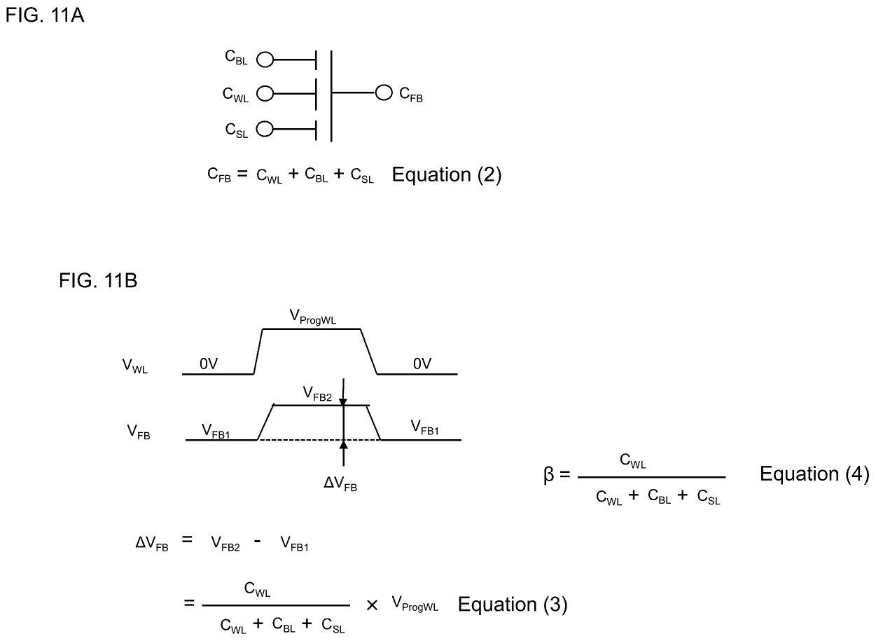

FIGS. 12A, 12B, and 12C are diagrams illustrating a read operation of the capacitorless DRAM memory cell of the related art.

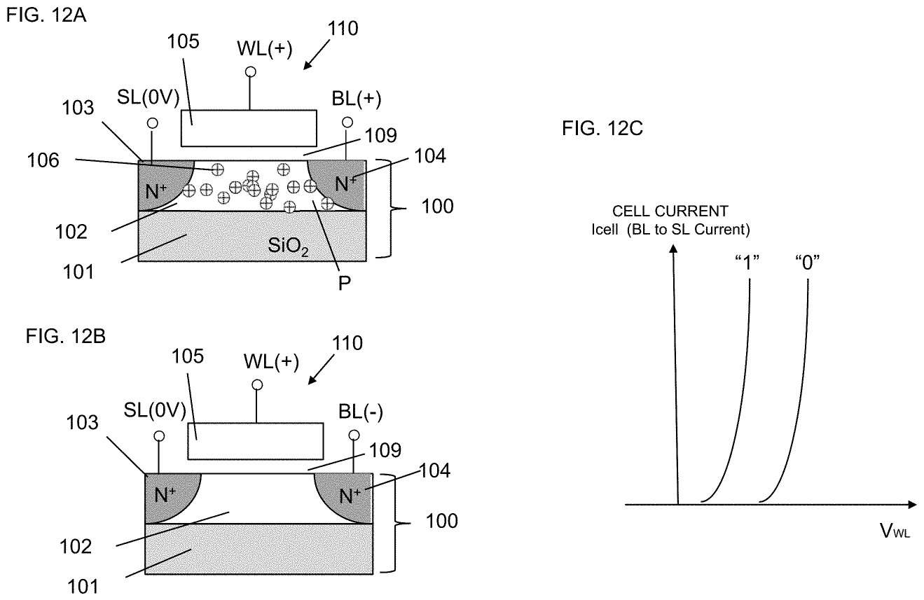

### DESCRIPTION OF EMBODIMENTS

Hereinafter, the structure of a memory device using a semiconductor element (hereinafter referred to as a dynamic flash memory) according to the present invention, a driving method thereof, and a method for manufacturing the memory device will be described with reference to the drawings.

### First Embodiment

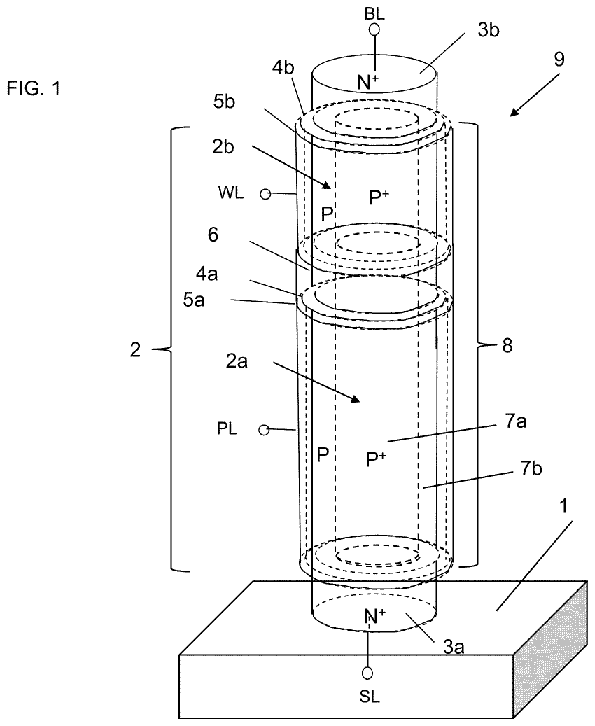

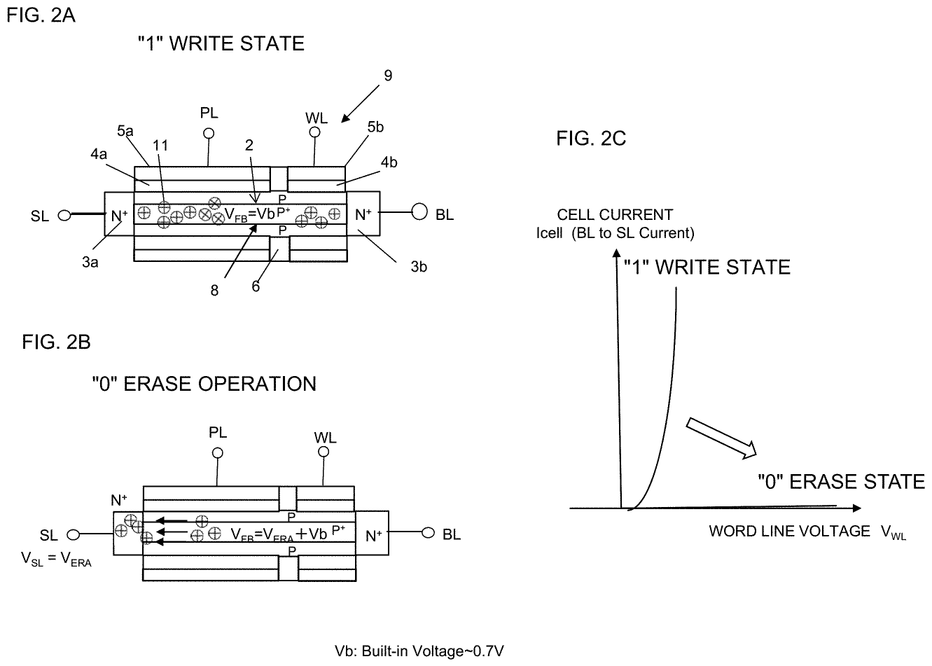

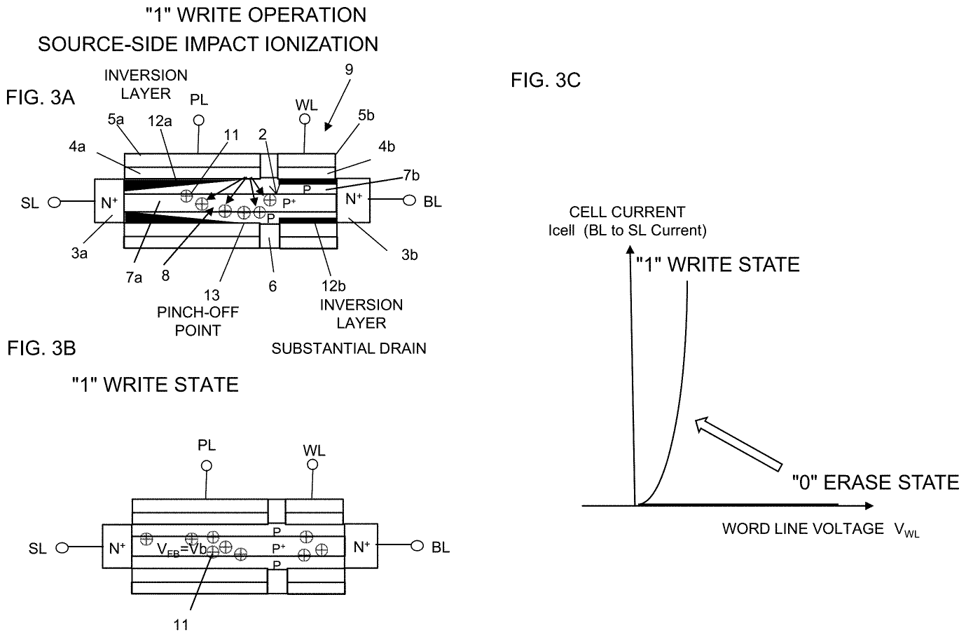

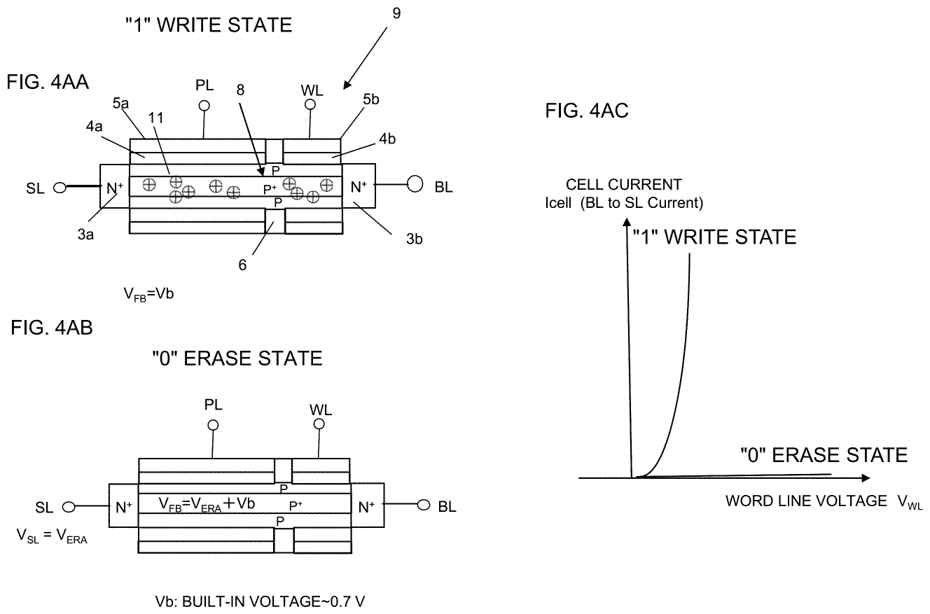

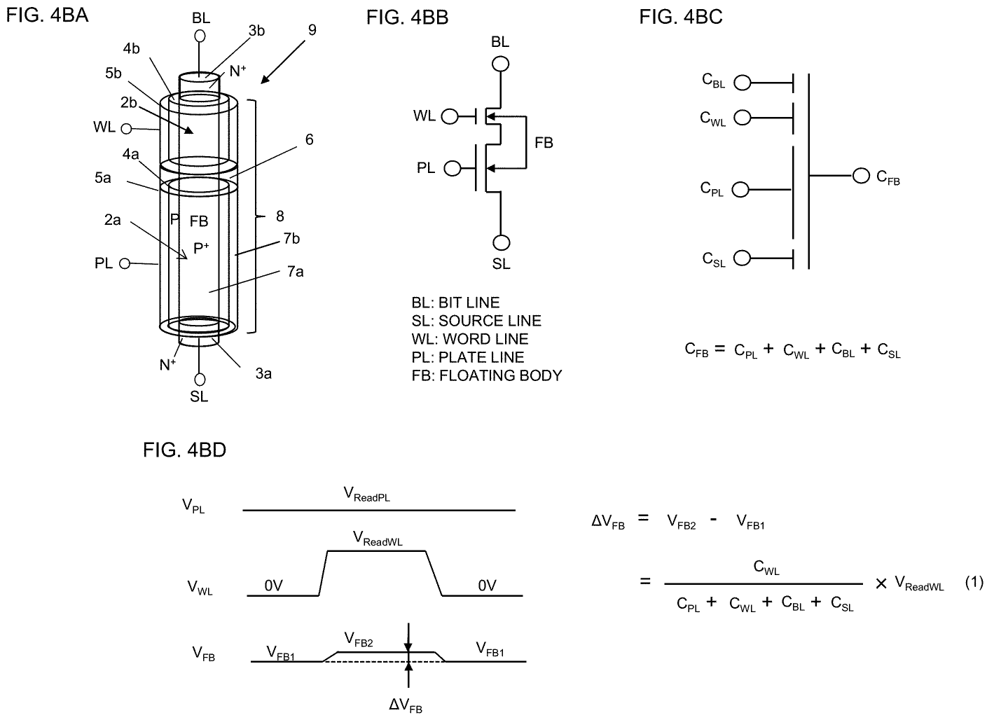

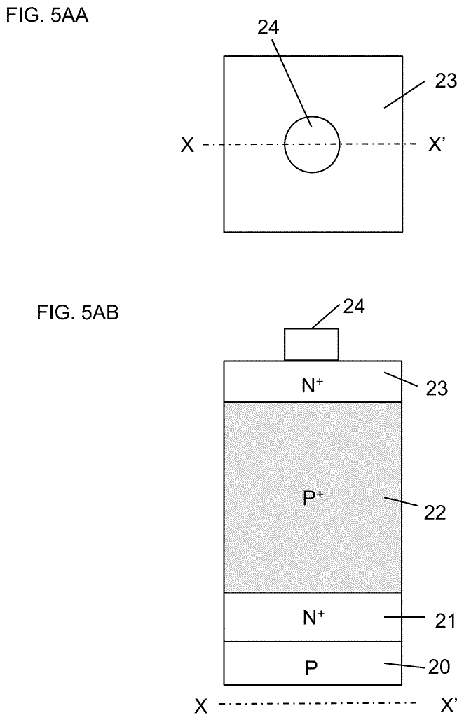

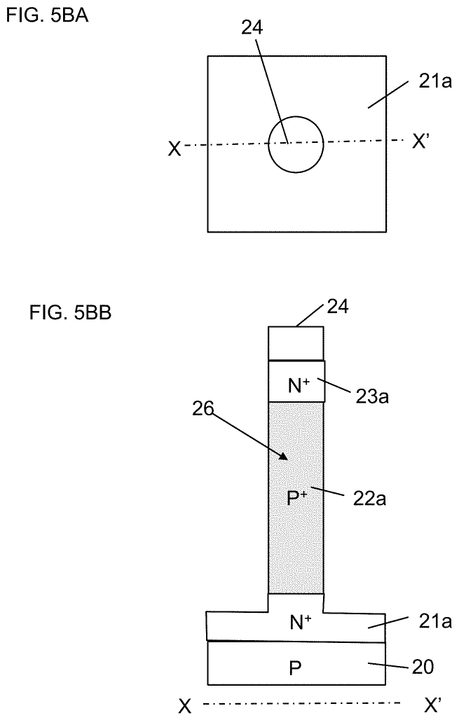

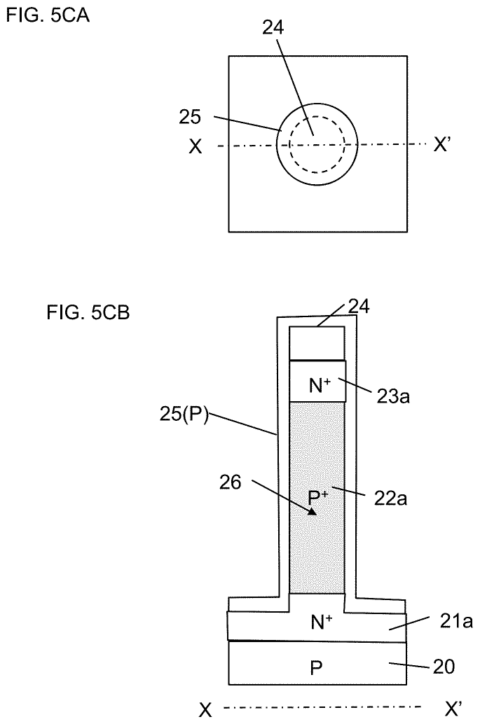

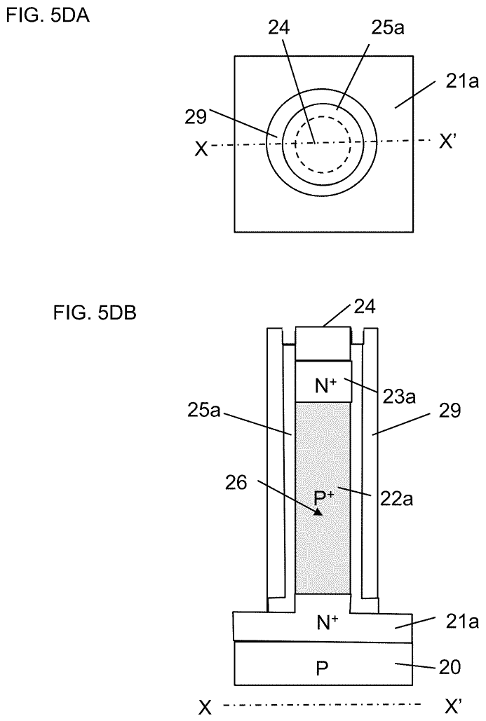

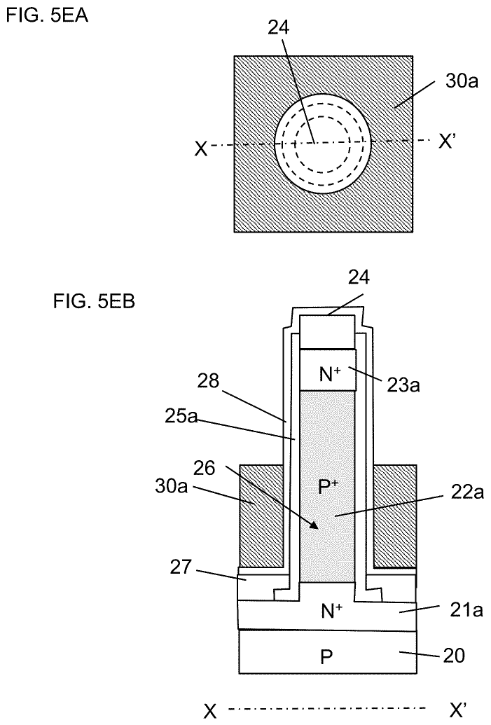

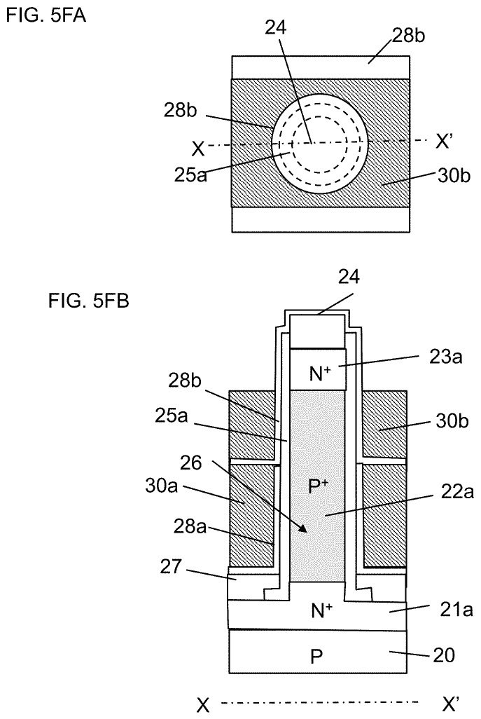

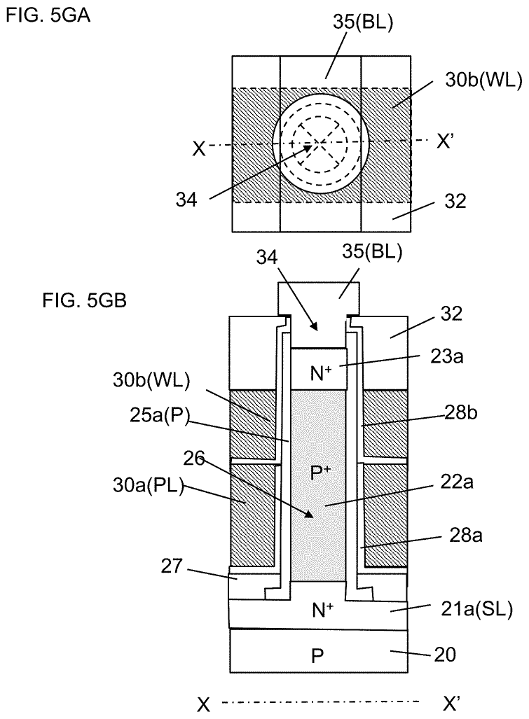

The structure and operation mechanism of a dynamic flash memory cell according to a first embodiment of the present invention, and a method for manufacturing the dynamic flash memory cell will be described with reference to FIGS. 1 to 5. The structure of the dynamic flash memory cell will be described with reference to FIG. 1. A data erasing mechanism will be described with reference to FIGS. 2A to 2C, a data writing mechanism will be described with reference to FIGS. 3A to 3C, and a data reading mechanism will be described with reference to FIGS. 4AA to 4AC and FIGS. 4BA to 4BD. A method for manufacturing a dynamic flash memory will be described with reference to FIG. 5.

FIG. 1 illustrates the structure of the dynamic flash memory cell according to the first embodiment of the present invention. A substrate 1 (an example of “substrate” in the claims) has thereon an N⁺ layer 3a (an example of “first impurity layer” in the claims). The N⁺ layer 3a has thereon a first silicon semiconductor pillar 2a (an example of “first semiconductor pillar” in the claims) (silicon semiconductor pillars are hereinafter referred to as “Si pillars”), and a second Si pillar 2b (an example of “second semiconductor pillar” in the claims) on top of the first Si pillar 2a. The first Si pillar 2a and the second Si pillar 2b form a Si pillar 2 (an example of “semiconductor pillar” in the claims). The Si pillar 2 has a P⁺ layer 7a (an example of “third impurity layer” in the claims) (a semiconductor region containing an acceptor impurity at a high concentration is hereinafter referred to as “P⁺ layer”) in a central portion thereof in plan view, and a P layer 7b (an example of “fourth impurity layer” in the claims) surrounding the P⁺ layer 7a and having a lower acceptor impurity concentration than the P⁺ layer 7a. The second Si pillar 2b has thereon an N⁺ layer 3b (an example of “second impurity layer” in the claims). A portion of the Si pillar 2 between the N⁺ layers 3a and 3b serves as a channel region 8 (an example of “channel region” in the claims). A first gate insulating layer 4a (an example of “first gate insulating layer” in the claims) surrounds the first Si pillar 2a, and a second gate insulating layer 4b (an example of “second gate insulating layer” in the claims) surrounds the second Si pillar 2b. A first gate conductor layer 5a (an example of “first gate conductor layer” in the claims) surrounds the first gate insulating layer 4a, and a second gate conductor layer 5b (an example of “second gate conductor layer” in the claims) surrounds the second gate insulating layer 4b. The first gate conductor layer 5a and the second gate conductor layer 5b are isolated from each other by an insulating layer 6. Accordingly, a dynamic flash memory cell 9 composed of the N⁺ layers 3a and 3b, the first Si pillar 2a, the second Si pillar 2b, the first gate insulating layer 4a, the second gate insulating layer 4b, the first gate conductor layer 5a, and the second gate conductor layer 5b is formed. The N⁺ layer 3a is connected to a source line SL, the N⁺ layer 3b is connected to a bit line BL, the first gate conductor layer 5a is connected to a plate line PL, and the second gate conductor layer 5b is connected to a word line WL. It is desirable to achieve a structure in which the first gate conductor layer 5a connected to the plate line PL has a larger gate capacitance than the second gate conductor layer 5b connected to the word line WL. In the memory device, a plurality of dynamic flash memory cells, each of which is described above, are two-dimensionally arranged on the substrate 1.

In FIG. 1, the first gate conductor layer 5a connected to the plate line PL has a longer gate length than the second gate conductor layer 5b connected to the word line WL so that the gate capacitance of the first gate conductor layer 5a can be larger than the gate capacitance of the second gate conductor layer 5b. Alternatively, a gate insulating film of the first gate insulating layer 4a may have a smaller thickness than a gate insulating film of the second gate insulating layer 4b instead of the first gate conductor layer 5a having a longer gate length than the second gate conductor layer 5b. Alternatively, the first gate insulating layer 4a may have a higher dielectric constant than the second gate insulating layer 4b. Further, any of the lengths of the gate conductor layers 5a and 5b, the thicknesses of the gate insulating layers 4a and 4b, and the dielectric constants of the gate insulating layers 4a and 4b may be combined so that the gate capacitance of the first gate conductor layer 5a can be larger than the gate capacitance of the second gate conductor layer 5b.

Alternatively, the first gate conductor layer 5a may be divided into two or more portions, which are operated synchronously or asynchronously as conductive electrodes for plate lines. Likewise, the second gate conductor layer 5b may be divided into two or more portions, which are operated synchronously or asynchronously as conductive electrodes for word lines. This also allows a dynamic flash memory operation to be performed.

An erase operation mechanism will be described with reference to FIGS. 2A to 2C. The channel region 8 between the N⁺ layers 3a and 3b is electrically isolated from the substrate 1 and serves as a floating body. FIG. 2A illustrates a state in which a hole group 11 generated by impact ionization in the previous cycle is stored in the channel region 8 before an erase operation is performed. Since the P⁺ layer 7a has a higher acceptor impurity concentration than the P layer 7b, the hole group 11 is mainly stored in the P⁺ layer 7a. At the time of the erase operation, as illustrated in FIG. 2B, the voltage of the source line SL is set to a negative voltage V_{ERA}. Here, V_{ERA} is −3 V, for example. As a result, the PN junction between the channel region 8 and the N⁺ layer 3a serving as the source to which the source line SL is connected is forward biased regardless of the value of an initial potential of the channel region 8. As a result, the hole group 11 stored in the channel region 8, which is generated by impact ionization in the previous cycle, is drawn into the N⁺ layer 3a corresponding to the source portion, and the channel region 8 has a potential V_{FB}, which is given by V_{FB}=V_{ERA}+Vb. Here, Vb is the built-in voltage across the PN junction and is about 0.7 V. When V_{ERA}=−3 V, the potential of the channel region 8 is −2.3 V. This value corresponds to the potential state of the channel region 8 in an erase state. If the potential of the channel region 8 serving as the floating body becomes a negative voltage, the threshold voltage of an N-channel MOS transistor of the dynamic flash memory cell 9 increases due to a substrate bias effect. This increases the threshold voltage of the second gate conductor layer 5b to which the word line WL is connected, as illustrated in FIG. 2C. The erase state of the channel region 8 corresponds to logical storage data “0”. In data reading, the voltage to be applied to the first gate conductor layer 5a connected to the plate line PL is set to be higher than the threshold voltage at the time of logical storage data “1” and lower than the threshold voltage at the time of logical storage data “0”, whereby a characteristic is obtained in which, as illustrated in FIG. 2C, no current flows even when the voltage of the word line WL is increased in reading of the logical storage data “0”. The condition of the voltages to be applied to the bit line BL, the source line SL, the word line WL, and the plate line PL, described above, and the potential of the floating body are an example for performing the erase operation, and other operation conditions under which the erase operation can be performed may be used. For example, the erase operation may be performed with a voltage difference applied between the bit line BL and the source line SL.

FIGS. 3A to 3C illustrate a write operation of the dynamic flash memory cell according to the first embodiment of the present invention. As illustrated in FIG. 3A, for example, 0 V is input to the N⁺ layer 3a to which the source line SL is connected, for example, 3 V is input to the N⁺ layer 3b to which the bit line BL is connected, for example, 2 V is input to the first gate conductor layer 5a to which the plate line PL is connected, and, for example, 5 V is input to the second gate conductor layer 5b to which the word line WL is connected. As a result, as illustrated in FIG. 3A, an annular inversion layer 12a is mainly formed on the P layer 7b in the channel region 8 inside the first gate conductor layer 5a to which the plate line PL is connected, and a first N-channel MOS transistor region composed of the channel region 8 (see FIG. 1) surrounded by the first gate conductor layer 5a is operated in a saturation region. This results in generation of a pinch-off point 13 in the inversion layer 12a on the inner side of the first gate conductor layer 5a to which the plate line PL is connected. In contrast, a second N-channel MOS transistor region composed of the channel region 8 (see FIG. 1) surrounded by the second gate conductor layer 5b to which the word line WL is connected is operated in a linear region. This results in formation of an inversion layer 12b, without a pinch-off point, over the entire channel region 8 inside the second gate conductor layer 5b to which the word line WL is connected. The inversion layer 12b formed over the entire inner side of the second gate conductor layer 5b to which the word line WL is connected serves as a substantial drain of the first N-channel MOS transistor region including the first gate conductor layer 5a. As a result, the electric field is maximized in a first boundary region of the channel region 8 between the first N-channel MOS transistor region including the first gate conductor layer 5a and the second N-channel MOS transistor region including the second gate conductor layer 5b, which are connected in series, and an impact ionization phenomenon occurs in this region. This region is a source-side region viewed from the second N-channel MOS transistor region including the second gate conductor layer 5b to which the word line WL is connected, and thus this phenomenon is referred to as a source-side impact ionization phenomenon. The source-side impact ionization phenomenon causes electrons to flow from the N⁺ layer 3a to which the source line SL is connected toward the N⁺ layer 3b to which the bit line BL is connected. The accelerated electrons collide with lattice Si atoms, and the kinetic energy of the collision generates electron-hole pairs. Some of the generated electrons flow to the first gate conductor layer 5a and the second gate conductor layer 5b, but most of them flow to the N⁺ layer 3b to which the bit line BL is connected. In “1” writing, electron-hole pairs may be generated using a gate induced drain leakage (GIDL) current, and the floating body FB (see FIG. 4BB) may be filled with the generated hole group (see NPL 7).

As illustrated in FIG. 3B, the generated hole group 11, which is majority carriers in the channel region 8, charges the channel region 8 to a positive bias. Since the N⁺ layer 3a to which the source line SL is connected is at 0 V, the channel region 8 is charged to the built-in voltage Vb (about 0.7 V) of the PN junction between the channel region 8 and the N⁺ layer 3a to which the source line SL is connected. Upon the channel region 8 being charged to a positive bias, the threshold voltages of the first N-channel MOS transistor region and the second N-channel MOS transistor region are decreased due to the substrate bias effect. This results in a decrease in the threshold voltage of the second N-channel MOS transistor region to which the word line WL is connected, as illustrated in FIG. 3C. The write state of the channel region 8 is assigned to the logical storage data “1”. The generated hole group 11 is mainly stored in the P⁺ layer 7a. As a result, a stable substrate bias effect can be obtained.

At the time of the write operation, electron-hole pairs may be generated by the impact ionization phenomenon or the GIDL current in a second boundary region between the N⁺ layer 3a and the channel region 8 or in a third boundary region between the N⁺ layer 3b and the channel region 8, instead of in the first boundary region described above, and the channel region 8 may be charged with the generated hole group 11. The condition of the voltages to be applied to the bit line BL, the source line SL, the word line WL, and the plate line PL, described above, is an example for performing the write operation, and other operation conditions under which the write operation can be performed may be used.

A read operation of the dynamic flash memory cell according to the first embodiment of the present invention will be described with reference to FIGS. 4AA to 4AC and FIGS. 4BA to 4BD. The read operation of the dynamic flash memory cell will be described with reference to FIG. 4AA to FIG. 4AC. As illustrated in FIG. 4AA, upon the channel region 8 being charged to the built-in voltage Vb (about 0.7 V), the threshold voltages of the N-channel MOS transistors are decreased due to the substrate bias effect. This state is assigned to the logical storage data “1”. As illustrated in FIG. 4AB, when the memory block to be selected before writing is performed is in the erase state “0” in advance, the channel region 8 is at a floating voltage V_{FB}, which is given by V_{ERA}+Vb. Through the write operation, the write state “1” is stored randomly. As a result, logical storage data of logic “0” and “1” is created for the word line WL. As illustrated in FIG. 4AC, the difference between the two threshold voltages for the word line WL is used to perform reading by using a sense amplifier. In data reading, the voltage to be applied to the first gate conductor layer 5a connected to the plate line PL is set to be higher than the threshold voltage at the time of logical storage data “1” and lower than the threshold voltage at the time of logical storage data “0”, whereby a characteristic is obtained in which, as illustrated in FIG. 4AC, no current flows even when the voltage of the word line WL is increased in reading of the logical storage data “0”.

Referring to FIG. 4BA to FIG. 4BD, a description will be given of the magnitude relationship of the gate capacitance between the two gate conductor layers, namely, the first gate conductor layer 5a and the second gate conductor layer 5b, at the time of the read operation of the dynamic flash memory cell according to the first embodiment of the present invention, and the operation related thereto. The gate capacitance of the second gate conductor layer 5b to which the word line WL is connected is desirably designed to be smaller than the gate capacitance of the first gate conductor layer 5a to which the plate line PL is connected. As illustrated in FIG. 4BA, the vertical length of the first gate conductor layer 5a to which the plate line PL is connected is set to be longer than the vertical length of the second gate conductor layer 5b to which the word line WL is connected to make the gate capacitance of the second gate conductor layer 5b to which the word line WL is connected smaller than the gate capacitance of the first gate conductor layer 5a to which the plate line PL is connected.

FIG. 4BB illustrates an equivalent circuit of one cell of the dynamic flash memory illustrated in FIG. 4BA. FIG. 4BC illustrates a coupling capacitance relationship of the dynamic flash memory. Here, C_{WL} is the capacitance of the second gate conductor layer 5b, C_{PL} is the capacitance of the first gate conductor layer 5a, C_{BL} is the capacitance of the PN junction between the channel region 8 and the N⁺ layer 3b serving as the drain, and C_{SL} is the capacitance of the PN junction between the channel region 8 and the N⁺ layer 3a serving as the source. As illustrated in FIG. 4BD, an oscillation of the voltage of the word line WL affects the channel region 8 as noise. A potential variation ΔV_{FB} of the channel region 8 at this time is expressed by the following equation.

ΔV_{FB}=C_{WL}/(C_{PL}+C_{WL}+C_{BL}+C_{SL})×V_{ReadWL} (1)

Here, V_{ReadWL} is the oscillating potential of the word line WL at the time of reading. As is apparent from Equation (1), a reduction in the contribution ratio of C_{WL} compared with the total capacitance C_{PL}+C_{WL}+C_{BL}+C_{SL} of the channel region 8 decreases ΔV_{FB}. The vertical length of the first gate conductor layer 5a to which the plate line PL is connected may further be set to be longer than the vertical length of the second gate conductor layer 5b to which the word line WL is connected to further decrease ΔV_{FB} without reducing the degree of integration of memory cells in plan view. The condition of the voltages to be applied to the bit line BL, the source line SL, the word line WL, and the plate line PL, described above, and the potential of the floating body are an example for performing the read operation, and other operation conditions under which the read operation can be performed may be used.

FIGS. 5AA and 5AB to FIGS. 5GA and 5GB illustrate a method for manufacturing the dynamic flash memory according to the first embodiment. FIG. 5AA is a plan view of a dynamic flash memory cell. FIG. 5AB is a vertical cross-sectional view taken along line X-X′ in FIG. 5AA. In an actual dynamic flash memory device, many dynamic flash memory cells are formed so as to be two-dimensionally arranged.

As illustrated in FIGS. 5AA and 5AB, an N⁺ layer 21, a P⁺ layer 22, and an N⁺ layer 23 are formed on a P-layer substrate 20 (an example of “substrate” in the claims) in this order from the bottom by epitaxial crystal growth, for example. Then, a mask material layer 24 having a circular shape in plan view is formed on the N⁺ layer 23. The mask material layer 24 may be formed of a plurality of material layers.

Then, as illustrated in FIGS. 5BA and 5BB, the N⁺ layer 23, the P⁺ layer 22, and an upper portion of the N⁺ layer 21 are etched using the mask material layer 24 as a mask to form a Si pillar 26 composed of an N⁺ layer 21a (an example of “first impurity layer” in the claims), a P⁺ layer 22a (an example of “third impurity layer” in the claims), and an N⁺layer 23a (an example of “second impurity layer” in the claims). In this etching, the upper portion of the N⁺ layer 21a is etched.

Then, as illustrated in FIGS. 5CA and 5CB, a P layer 25 of Si is formed on the entire surface using, for example, an ALD (Atomic Layer Deposition) method.

Then, a SiO₂ layer (not illustrated) is applied to cover the entire P layer 25. Then, the SiO₂ layer is etched by a RIE (Reactive Ion Etching) method. Thus, as illustrated in FIGS. 5DA and 5DB, a SiO₂ layer 29 is formed on a side surface of the P layer 25. Then, the P layer 25 is etched using the mask material layer 24 and the SiO₂ layer 29 as a mask to form a P layer 25a (an example of “fourth impurity layer” in the claims). In this case, the top portion of the P layer 25a is etched by about an amount corresponding to the film thickness of the P layer 25a.

Then, the SiO₂ layer 29 is removed. Then, as illustrated in FIGS. 5EA and 5EB, a SiO₂ layer 27 is formed around the P layer 25a in such a manner as to cover the bottom portion of the P layer 25a. Then, a HfO₂ layer 28 serving as a gate insulating layer is formed to cover the entire surface. Then, for example, a TiN layer 30a (an example of “first gate conductor layer” in the claims) is formed, which is a gate conductor layer surrounding a lower side surface of the HfO₂ layer 28.

Next, as illustrated in FIGS. 5FA and 5FB, the exposed HfO₂ layer 28 is etched to form a HfO₂ layer 28a (an example of “first gate insulating layer” in the claims). Then, a HfO₂ layer 28b (an example of “second gate insulating layer” in the claims) serving as a gate insulating layer is formed on the entire surface. Then, for example, a TiN layer 30b (an example of “second gate conductor layer” in the claims) is formed, which is a gate conductor layer surrounding a side surface of the HfO₂ layer 28b and having an upper surface positioned near a lower end of the N⁺ layer 23a.

Then, as illustrated in FIGS. 5GA and 5GB, a SiO₂ layer 32 is formed on the TiN layer 30b such that an upper surface thereof is positioned at the position of an upper surface of the mask material layer 24. Then, the mask material layer 24 on top of the N⁺ layer 23a is removed to form a contact hole 34. Then, a conductive electrode layer 35 connected to the N⁺ layer 23a is formed on the SiO₂ layer 32 so as to extend in a direction perpendicular to the TiN layer 30b in plan view. The N⁺ layer 21a is connected to the source line SL, the TiN layer 30a is connected to the plate line (PL), the TiN layer 30b is connected to the word line WL, and the N⁺ layer 23a is connected to the bit line BL via the conductive electrode layer 35. As a result, a dynamic flash memory cell is formed on the P-layer substrate 20.

In FIG. 1, the first Si pillar 2a and the second Si pillar 2b having a rectangular vertical cross section are used. However, the vertical cross section shape of the first Si pillar 2a and the second Si pillar 2b may be trapezoidal. Further, the first Si pillar 2a and the second Si pillar 2b may have different vertical cross sections such as a rectangular shape and a trapezoidal shape. A portion of the Si pillar 26 in FIGS. 5AA and 5AB to FIGS. 5GA and 5GB surrounded by the TiN layer 30a, which corresponds to the first Si pillar 2a, and a portion of the Si pillar 26 surrounded by the TiN layer 30b, which corresponds to the second Si pillar 2b, may have rectangular and trapezoidal shapes.

In FIG. 1, even if the first gate conductor layer 5a surrounds a portion of the first gate insulating layer 4a, the dynamic flash memory operation can be performed. Even if the first gate conductor layer 5a is divided into a plurality of conductor layers and the conductor layers are driven synchronously or asynchronously, the dynamic flash memory operation can be performed. Likewise, even if the second gate conductor layer 5b is divided into a plurality of conductor layers and the conductor layers are driven synchronously or asynchronously, the dynamic flash memory operation can be performed. In FIGS. 5AA and 5AB to FIGS. 5GA and 5GB, the TiN layer 30a corresponding to the first gate conductor layer 5a may be divided, and the TiN layer 30b corresponding to the second gate conductor layer 5b may be divided.

In FIG. 1, the first gate conductor layer 5a may be connected to the word line WL, and the second gate conductor layer 5b may be connected to the plate line PL. With this configuration, the dynamic flash memory operation described above can also be performed. In this case, in FIGS. 5GA and 5GB, the TiN layer 30a is connected to the word line WL, and the TiN layer 30b is connected to the plate line PL.

In FIG. 1, the N⁺ layer 3a may extend over the substrate 1 to serve also as a wiring conductor layer for the source line SL. Alternatively, a conductor layer such as a W layer may be connected to the N⁺ layer 3a. Further, a conductor layer made of metal or an alloy, such as a W layer, may be connected to the N⁺ layer 3a outside a region where a larger number of first Si pillars 2a and second Si pillars 2b are formed two-dimensionally. The same applies to the N⁺ layer 21a in FIGS. 5AA and 5AB to FIGS. 5GA and 5GB.

Even a structure in which the N⁺ layers 3a and 3b, the P⁺ layer 7a, and the P layer 7b have conductivity reversed in polarity from that described above can also implement the dynamic flash memory operation. In this case, electrons are majority carriers in the N-type first Si pillar 2a and the N-type second Si pillar 2b. Accordingly, the electron group generated by impact ionization is stored in the channel region 8, and the “1” state is set. The same applies to the relationship among the N⁺ layers 21a and 23a, the P⁺ layer 22a, and the P layer 25a in FIGS. 5AA and 5AB to FIGS. 5GA and 5GB.

The N⁺ layers 21a and 23a are formed by the formation of the N⁺ layers 21 and 23 before the Si pillar 26 is formed. Alternatively, the N⁺ layers 21a and 23a may be formed, after the Si pillar 26 is formed, by using ion implantation, epitaxial crystal growth, or the like.

This embodiment provides the following features.

### (Feature 1)

In the dynamic flash memory cell according to the first embodiment of the present invention, the voltage of the word line WL oscillates up and down in a write or read operation. At this time, the plate line PL serves to reduce the capacitive coupling ratio between the word line WL and the channel region 8. This results in a significant reduction in the influence of the change in voltage across the channel region 8 caused by the up and down oscillation of the voltage of the word line WL. Accordingly, the difference between the threshold voltages indicating logic “0” and logic “1” can be increased. This leads to an increase in the operation margin of the dynamic flash memory cell.

### (Feature 2)

In this embodiment, the hole group 11 generated by the impact ionization phenomenon is mainly stored in the P⁺ layer 7a (corresponding to the P⁺ layer 22a in FIGS. 5AA and 5AB to FIGS. 5GA and 5GB). An electronic current flowing between the N⁺ layers 3a and 3b in the read operation flows through the P layer 7b (corresponding to the P layer 25a in FIGS. 5AA and 5AB to FIGS. 5GA and 5GB). Accordingly, in the read operation, the channel of the electronic current in the P layer 7b and the floating body in the P⁺ layer 7a where the hole group 11 is stored are separated from each other, and a more stable floating body voltage is maintained. This enables a stable operation of the dynamic flash memory, leading to high performance.

### (Feature 3)

In this embodiment, as illustrated in FIGS. 5BA and 5BB and FIGS. 5CA and 5CB, after the Si pillar 26 composed of the P⁺ layer 22a is formed, the P layer 25a is formed so as to uniformly cover the side surface of the P⁺ layer 22a by using the ALD method, for example. This facilitates the formation of the P⁺ layer 22a and the P layer 25a having different acceptor impurity concentrations. The separate formation of the P⁺ layer 22a and the P layer 25a enables the semiconductor materials of the P⁺ layer 22a and the P layer 25a to be selected in accordance with the dynamic flash memory operation. As a result, the structure of a dynamic flash memory can be more flexibly designed. This leads to high performance of the dynamic flash memory.

### Second Embodiment

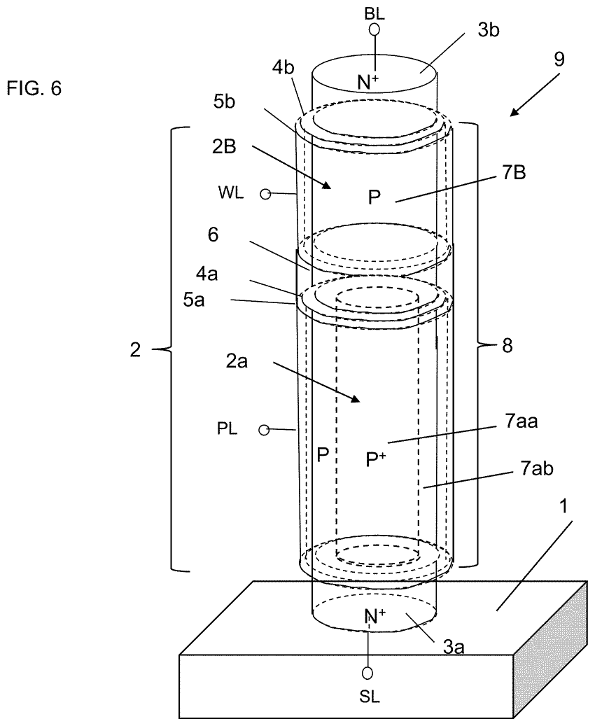

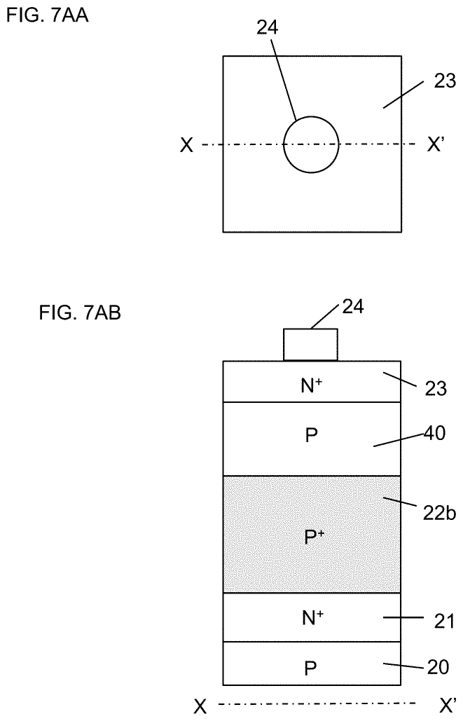

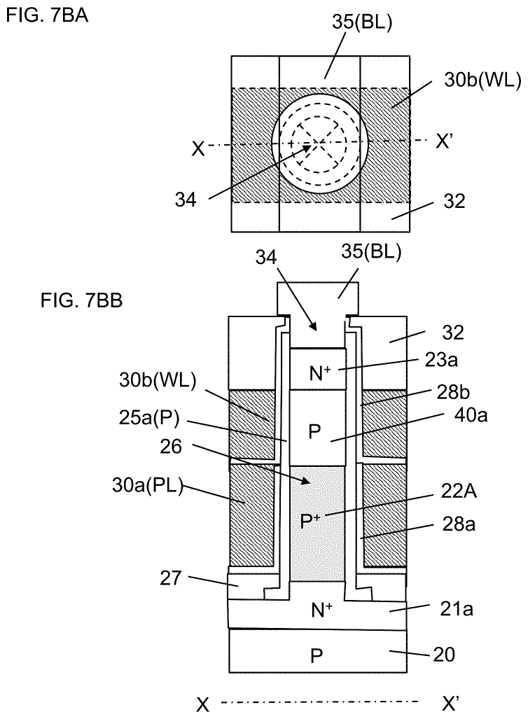

The structure of a dynamic flash memory according to a second embodiment and a method for manufacturing the dynamic flash memory will be described with reference to FIG. 6, FIGS. 7AA and 7AB, and FIGS. 7BA and 7BB. In an actual memory device, many dynamic flash memory cells 9 are arranged in rows and columns on a substrate 1. In FIG. 6, FIGS. 7AA and 7AB, and FIGS. 7BA and 7BB, components that are the same as or similar to those in FIG. 1 are denoted by the same reference numerals.

As illustrated in FIG. 6, the entirety of a second Si pillar 2B is a P layer 7B. The first silicon pillar 2a has a P⁺ layer 7aa in a center portion thereof, and a P layer lab surrounding the P⁺ layer 7aa. Other components are the same as those in FIG. 1. In the vertical direction, the boundary between the P⁺ layer 7aa and the P layer 7B of the Si pillar 2B may be located within the insulating layer 6 or at the first Si pillar 2a or the second Si pillar 2B near the insulating layer 6.

As illustrated in FIGS. 7AA and 7AB, an N⁺ layer 21, a P⁺ layer 22b, a P layer 40, and an N⁺ layer 23 are formed on a P-layer substrate 20 in this order from the bottom by epitaxial crystal growth, for example. Then, a mask material layer 24 is formed on the N⁺ layer 23. As described above, in this embodiment, the P⁺ layer 22 in FIGS. 5AA and 5AB is formed into the P⁺ layer 22b and the P layer 40.

Next, the same steps as those in FIGS. 5BA and 5BB to FIGS. 5GA and 5GB are performed. As a result, as illustrated in FIGS. 7BA and 7BB, a P⁺ layer 22A is formed on the entire portion of the silicon pillar 26 surrounded by the TiN layer 30a connected to the plate line PL. Then, a P layer 40a is formed on the entire portion of the Si pillar 26 surrounded by the TiN layer 30b connected to the word line WL. Other components are the same as those illustrated in FIGS. 5BA and 5BB to FIGS. 5GA and 5GB. As a result, a dynamic flash memory cell is formed on the P-layer substrate 20. The boundary between the P⁺ layer 22A and the P layer 40a may be located above or below the position of the bottom portion of the HfO₂ layer 28b in the vertical direction.

The first gate conductor layer 5a may be connected to the word line WL, and the second gate conductor layer 5b may be connected to the plate line PL. In this case, the vertical relationship between the first Si pillar 2a and the second Si pillar 2B is reversed.

This embodiment provides the following features.

### (Feature 1)

As illustrated in FIG. 6, in this embodiment, the hole group for the “1” data writing is stored in the P⁺ layer 7aa (corresponding to the P⁺ layer 22A in FIGS. 7BA and 7BB) in the first Si pillar 2a compared with FIG. 1. Thus, the variation of the floating body voltage of the P⁺ layer 7aa caused by an address pulse voltage applied to the word line WL is suppressed. This enables a stable operation of the dynamic flash memory.

### (Feature 2)

In this embodiment, the entirety of the second Si pillar 2B illustrated in FIG. 6 is the P layer 7B, which enables the entire second Si pillar 2B to be operated as a channel of an electronic current for reading “1” and “0”. As a result, a high-speed dynamic flash memory operation can be achieved.

### (Feature 3)

As described with reference to FIGS. 7AA and 7AB, the P layer 40 can be easily formed on the P⁺ layer 22b by epitaxial crystal growth. The P layer 40a is formed from the P layer 40.

### Third Embodiment

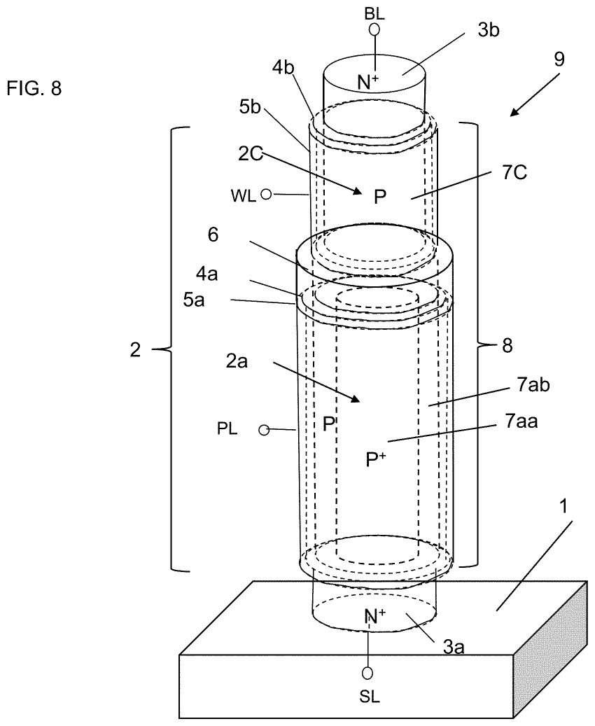

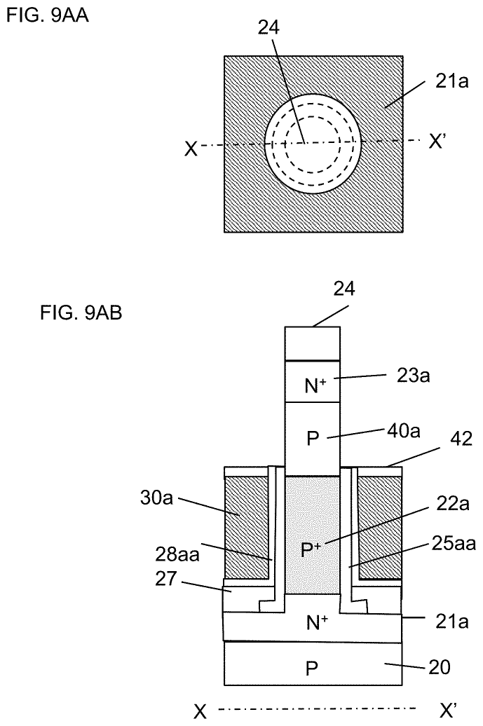

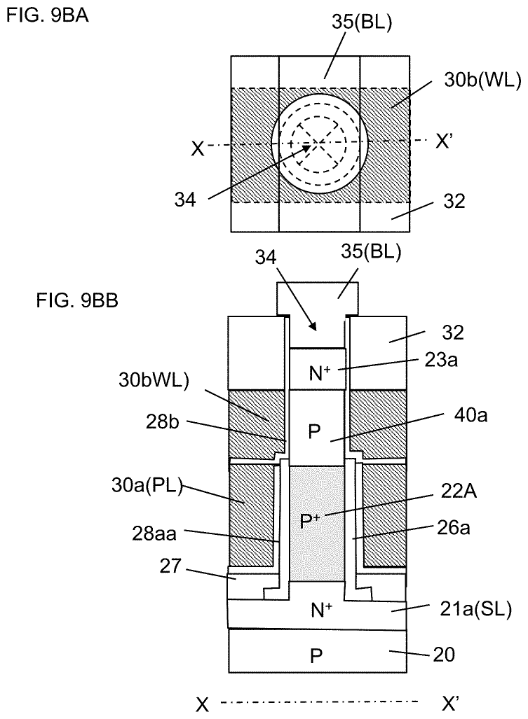

The structure of a dynamic flash memory according to a third embodiment will be described with reference to FIG. 8. A method for manufacturing the dynamic flash memory according to the third embodiment will be described with reference to FIGS. 9AA and 9AB and FIGS. 9BA and 9BB. In an actual memory device, many dynamic flash memory cells 9 are arranged in rows and columns on a substrate 1. In FIG. 8, FIGS. 9AA and 9AB, and FIGS. 9BA and 9BB, components that are the same as or similar to those in FIG. 1, FIGS. 5AA and 5AB to FIGS. 5GA and 5GB, FIG. 6, and FIGS. 7BA and 7BB are denoted by the same reference numerals.

As illustrated in FIG. 8, a second Si pillar 2C is formed such that the outer peripheral edge of the second Si pillar 2C is inside the outer peripheral edge of the first Si pillar 2a in plan view. The first silicon pillar 2a has a P⁺ layer 7aa in a center portion thereof, and a P layer lab surrounding the P⁺ layer 7aa. The second Si pillar 2C is formed of a P layer 7C. Other components are the same as those in FIG. 6. In the vertical direction, the boundary between the P⁺ layer 7aa and the P layer 7C may be located within the insulating layer 6 or at the first Si pillar 2a or the second Si pillar 2C near the insulating layer 6.

As illustrated in FIGS. 9AA and 9AB, after the TiN layer 30a is formed, a SiO₂ layer 42 is formed on the TiN layer 30a. Then, a portion of the HfO₂ layer 28 (illustrated in FIGS. 5EA and 5EB) and a portion of the P layer 25a (illustrated in FIGS. 5EA and 5EB), which are above an upper surface of the SiO₂ layer 42, are etched to form a HfO₂ layer 28aa and a P layer 25aa. The etching of the P layer 25a may be performed up to the surface layer of the P layer 40a. The removal of the P layer 25a may be performed by oxidizing the portion of the P layer 25a and removing the oxide film.

Next, as illustrated in FIGS. 9BA and 9BB, the SiO₂ layer 42 is removed. Then, a SiO₂ layer 32 is formed on the TiN layer 30b such that an upper surface thereof is positioned at the position of an upper surface of the mask material layer 24. Then, the mask material layer 24 on top of the N⁺ layer 23a is removed to form a contact hole 34. Then, a conductive electrode layer 35 connected to the N⁺ layer 23a is formed on the SiO₂ layer 32 so as to extend in a direction perpendicular to the TiN layer 30b in plan view. The N⁺ layer 21a is connected to the source line SL, the TiN layer 30a is connected to the plate line (PL), the TiN layer 30b is connected to the word line WL, and the N⁺ layer 23a is connected to the bit line BL via the conductive electrode layer 35. As a result, a dynamic flash memory cell is formed on the P-layer substrate 20. The SiO₂ layer 42 may be left without being removed.

This embodiment provides the following feature.

### (Feature 1)

In this embodiment, as illustrated in FIG. 8, the hole group for the “1” data writing is accumulated in the P⁺ layer 7aa (corresponding to the P⁺ layer 22A in FIGS. 9BA and 9BB). In this case, the first Si pillar 2a having the P⁺ layer 7aa mainly serves as an accumulation portion of the hole group. The second Si pillar 2C formed by the P layer 7C mainly serves as a switching channel for reading “1” and “0”. Accordingly, the first Si pillar 2a is formed such that the outer peripheral edge of the first Si pillar 2a is outside the outer peripheral edge of the second Si pillar 2C, which makes it possible to easily form second gate conductor layers 5b that are connected to each other in a first direction and isolated from each other in a direction perpendicular to the first direction and that are to be connected to word lines. As a result, a high-integration dynamic flash memory can be achieved.

### OTHER EMBODIMENTS

In the first embodiment, the first gate conductor layer 5a connected to the plate line PL may be formed of a single conductor material layer or a combination of multiple conductor material layers. Likewise, the second gate conductor layer 5b connected to the word line WL may be formed of a single conductor material layer or a combination of multiple conductor material layers. The outer side of each gate conductor layer may be connected to a wiring metal layer such as W. The same applies to the other embodiments according to the present invention.

In FIG. 1, the vertical length of the first gate conductor layer 5a to which the plate line PL is connected is set to be longer than the vertical length of the second gate conductor layer 5b to which the word line WL is connected such that C_{PL}>C_{W} is met. However, only addition of the plate line PL results in a reduction in the capacitive coupling ratio of the word line WL to the channel region 8 (C_{WL}/(C_{PL}+C_{WL}+C_{BL}+C_{SL})). As a result, the potential variation ΔV_{FB} of the channel region 8 of the floating body is reduced.

In the description of the first embodiment, as the voltage of the plate line PL, for example, a fixed voltage of 2 V may be applied regardless of the operation mode. As the voltage of the plate line PL, for example, 0 V may be applied only at the time of erasing. The voltage of the plate line PL may be a fixed voltage or a voltage that changes with time as long as the voltage satisfies a condition in which a dynamic flash memory operation can be performed.

In the first embodiment, the first Si pillar 2a and the second Si pillar 2b has a circular shape in plan view. Alternatively, the shape of the first Si pillar 2a and the second Si pillar 2b in plan view may be a circle, an ellipse, a shape elongated in one direction, or the like. Also in a logic circuit region formed away from the dynamic flash memory cell region, Si pillars having different shapes in plan view can be formed in a mixed manner in the logic circuit region in accordance with the logic circuit design. These also apply to the other embodiments according to the present invention.

In the first embodiment, one or both of the first gate conductor layer 5a and the second gate conductor layer 5b may be divided into a plurality of conductor layers. The same applies to the other embodiments according to the present invention.

In the description of the first embodiment, at the time of the erase operation, the source line SL is negatively biased to extract the hole group in the channel region 8, which is the floating body FB. The erase operation may be performed with the bit line BL negatively biased instead of the source line SL or with both the source line SL and the bit line BL negatively biased. Alternatively, the erase operation may be performed under other voltage conditions. The same applies to the other embodiments according to the present invention.

In FIG. 1, an N-type or P-type impurity layer may be disposed between the N⁺ layer 3a and the first Si pillar 2a. An N-type or P-type impurity layer may be disposed between the N⁺ layer 3b and the second Si pillar 2b. The same applies to the other embodiments according to the present invention.

In FIG. 1, the P⁺ layer 7a and the P layer 7b may be formed as different semiconductor material layers. The P⁺ layer 7a may have different acceptor impurity concentrations between the first Si pillar 2a and the second Si pillar 2b. Likewise, the P layer 7b may have different acceptor impurity concentrations between the first Si pillar 2a and the second Si pillar 2b. The same applies to the other embodiments according to the present invention.

In the first embodiment, the N⁺ layers 3a and 3b may be formed as layers made of any other semiconductor material containing a donor impurity. The N⁺ layer 3a and the N⁺ layer 3b may be formed as different semiconductor material layers.

In FIG. 1, the boundary between the channel region 8 and each of the first Si pillar 2a and the second Si pillar 2b in the vertical direction may be located at the position of the insulating layer 6 or in an upper portion of the first Si pillar 2a or a lower portion of the second Si pillar 2b. The same applies to the other embodiments according to the present invention.

Various embodiments and modifications can be made to the present invention without departing from the broad spirit and scope of the present invention. The embodiments described above are for explaining an example of the present invention, and do not limit the scope of the present invention. The embodiments and modifications described above can be combined as desired. Some of the components may be removed as necessary from the embodiments described above to form other embodiments within scope of the technical idea of the present invention.

### INDUSTRIAL APPLICABILITY

A method for manufacturing a memory device using a semiconductor element according to the present invention provides a high-density and high-performance dynamic flash memory.

1. A method for manufacturing a memory device using a semiconductor element, the memory device being configured to control voltages to be applied to a first gate conductor layer, a second gate conductor layer, a first impurity layer, and a second impurity layer to perform a data write operation, a data read operation, and a data erase operation, the method comprising the steps of:
forming a semiconductor pillar standing on a substrate in a vertical direction to the substrate and having a third impurity layer and a fourth impurity layer on either or both of a lower portion and an upper portion of the semiconductor pillar, the third impurity layer being located in a central portion of the semiconductor pillar as viewed in a horizontal cross section, the fourth impurity layer surrounding the third impurity layer and having a lower impurity concentration than the third impurity layer;
forming a first gate insulating layer surrounding a side surface of a first semiconductor pillar in the lower portion of the semiconductor pillar;
forming the first gate conductor layer surrounding a side surface of the first gate insulating layer;
forming a second gate insulating layer connected to the first gate insulating layer and surrounding a side surface of a second semiconductor pillar in the upper portion of the semiconductor pillar;
forming the second gate conductor layer so as to surround a side surface of the second gate insulating layer;
forming the first impurity layer connected to a bottom portion of the semiconductor pillar before or after forming the semiconductor pillar; and
forming the second impurity layer at a top portion of the semiconductor pillar before or after forming the semiconductor pillar.

2. The method for manufacturing a memory device using a semiconductor element according to claim 1, wherein
the third impurity layer is formed to be connected to the first impurity layer and the second impurity layer, and
the fourth impurity layer is formed to be connected to the first impurity layer and the second impurity layer.

3. The method for manufacturing a memory device using a semiconductor element according to claim 1, further comprising the steps of:
forming a first impurity layer pillar having the third impurity layer at least in a lower portion thereof; and
forming the fourth impurity layer so as to surround the first impurity layer pillar to form the semiconductor pillar.

4. The method for manufacturing a memory device using a semiconductor element according to claim 1, wherein the second semiconductor pillar surrounded by the second gate insulating layer is formed of a fifth impurity layer having a lower impurity concentration than the first impurity layer.

5. The method for manufacturing a memory device using a semiconductor element according to claim 4, wherein the semiconductor pillar is formed such that, in plan view, an outer peripheral edge of a portion of the semiconductor pillar surrounded by second gate insulating layer is inside an outer peripheral edge of a portion of the semiconductor pillar surrounded by the first gate insulating layer.

6. The method for manufacturing a memory device using a semiconductor element according to claim 1, wherein the third impurity layer and the fourth impurity layer are formed as different semiconductor material layers.

7. The method for manufacturing a memory device using a semiconductor element according to claim 1, wherein a first gate capacitance between the first gate conductor layer and the semiconductor pillar is larger than a second gate capacitance between the second gate conductor layer and the semiconductor pillar.

8. The method for manufacturing a memory device using a semiconductor element according to claim 1, wherein
the memory device is configured to perform the data write operation for controlling the voltages to be applied to the first gate conductor layer, the second gate conductor layer, the first impurity layer, and the second impurity layer to hold in the semiconductor pillar a hole group or an electron group serving as majority carriers in the semiconductor pillar, the hole group or electron group being formed by an impact ionization phenomenon or a gate induced drain leakage current, and perform the data erase operation for controlling the voltages to be applied to the first gate conductor layer, the second gate conductor layer, the first impurity layer, and the second impurity layer to discharge the hole group or the electron group serving as the majority carriers in the semiconductor pillar from within the semiconductor pillar.
